(19) United States
(12) Patent Application Publication
(10) Pub. No.: US 2025/0147104 A1
(43) Pub. Date: May 8, 2025

(54) DEVICES AND METHODS FOR DETERMINING AND EXTENDING A REMAINING USEFUL LIFE OF A BATTERY

(71) Applicant: ZEBRA TECHNOLOGIES CORPORATION, Lincolnshire, IL (US)

(72) Inventors: Charles W. Roark, Frisco, TX (US); Ajay Sood, Bangalore (IN)

(21) Appl. No.: 18/386,428

(22) Filed: Nov. 2, 2023

(51) Int. Cl. G01R 31/367; G01R 31/382

(52) U.S. Cl. CPC G01R 31/367; G01R 31/382

(57) ABSTRACT

Devices and methods for determining and extending a remaining useful life of a battery are disclosed herein. In an embodiment, the method receives temperature information and state of charge information of the first battery over a duration of time and metric data of the first battery over the duration of time. The method trains a machine learning model based on historical data associated with one or more other batteries and utilizes the trained machine learning model to determine a remaining useful life of the first battery based on the temperature information, the state of charge information, and the metric data. In an embodiment, the method also receives environment information of the first battery, trains a machine learning model, and utilizes the trained machine learning model to determine at least one mitigation to extend the remaining useful life of the first battery based on the temperature information, the state of charge information, the metric data, and the environment information.

### BACKGROUND

A facility (e.g., a hardware store, a warehouse, a fulfillment center, a grocery store, a convenience store, a retail store, a hospital, an airport, a manufacturing plant, a shipping center, etc.) can deploy a device (e.g., a phone, a wearable, a mobile computer, a tablet, a barcode scanner, a quick response (QR) code scanner, an RFID reader, a robot, etc.) or a fleet (e.g., tens, hundreds, thousands, etc.) of devices having respective one or more batteries to assist with the execution of tasks and workflows. For example, an associate of a facility can utilize a device to identify each item displayed on a display module of the facility by scanning each item and/or processing an associated label thereof (e.g., a Stock Keeping Unit (SKU) or a product code). Additionally, based on the identification, an associate can perform other tasks including, but not limited to, locating, picking, and/or re-stocking each item displayed on the display module.

The device or fleet of devices may rely on the respective one or more batteries to store and supply power to the device or the fleet of devices and components thereof. As such, the respective one or more batteries provide for maintaining devices operable. To maintain the device or fleet of devices operable, the respective one or more batteries may require replacement at expiration or the end of a useful life (e.g., when the respective one or more batteries cannot receive or hold a charge above a threshold percentage of a rated capacity thereof). Otherwise, the device or fleet of devices may be rendered inoperable thereby impeding the functioning of a facility (e.g., the execution of tasks and workflows by an associate of a facility). As such, there is a need to automatically and accurately determine a remaining useful life of a battery to facilitate the replacement of the battery. Additionally, there is also a need to automatically determine a mitigation to extend the useful life of a battery to maximize a life of the battery.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a diagram illustrating an embodiment of a system of the present disclosure.

FIG. 2 is a diagram illustrating a server device of FIG. 1 in accordance with an embodiment of the present disclosure.

FIG. 3 is a flowchart illustrating processing steps carried out by an embodiment of the present disclosure.

FIG. 4 is a diagram illustrating one or more processing steps carried out by the embodiment of FIG. 3.

FIG. 5 is a flowchart illustrating processing steps carried out by an embodiment of the present disclosure.

FIG. 6 is a diagram illustrating one or more processing steps carried out by the embodiment of FIG. 5.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

As mentioned above, a facility (e.g., a hardware store, a warehouse, a fulfillment center, a grocery store, a convenience store, a retail store, a hospital, an airport, a manufacturing plant, a shipping center, etc.) can deploy a device (e.g., a phone, a wearable, a mobile computer, a tablet, a barcode scanner, a QR code scanner, an RFID reader, a robot, etc.) or a fleet (e.g., tens, hundreds, thousands, etc.) of devices having respective one or more batteries to assist with the execution of tasks and workflows. The device or fleet of devices may rely on the respective one or more batteries to store and supply power to the device or the fleet of devices and components thereof. As such, the respective one or more batteries provide for maintaining devices operable. To maintain the device or fleet of devices operable, the respective one or more batteries may require replacement at expiration or the end of a useful life (e.g., when the respective one or more batteries cannot receive or hold a charge above a threshold percentage of a rated capacity thereof). Otherwise, the device or fleet of devices may be rendered inoperable thereby impeding the functioning of a facility (e.g., the execution of tasks and workflows by an associate of a facility). As such, there is a need to automatically and accurately determine a remaining useful life of a battery to facilitate the replacement of the battery. Additionally, there is also a need to automatically determine a mitigation to extend the useful life of a battery to maximize a life of the battery.

A battery may include one or more cells and may degrade over a period of use. Generally, use of a battery is rated as reliable (e.g., at the time of manufacture) until the battery reaches a fixed charge-related threshold. For example, a battery may reach an end of useful life when the battery cannot receive or hold a charge above a threshold percentage of a rated capacity of the battery. Additionally, or alternatively, the battery may be considered to have reached the end of useful life after undergoing a threshold quantity of charge cycles. In such cases, while the battery may be capable of continuing to power a device for a particular period of time beyond the fixed threshold, at such a point, a degradation rate of the battery may relatively quickly increase and/or a reliability of the battery may relatively quickly decrease. Accordingly, such fixed thresholds are generally utilized to determine when a battery is to be replaced (e.g., to prevent or reduce the probability of a battery and/or a device that relies on power from the battery from becoming inoperable and/or the probability of a battery becoming ineffective to support the functioning of a facility).

However, impactful information, circumstances and/or conditions of a battery (e.g., temperature information, state of charge information, environmental information, etc.) can provide for automatically and accurately determining a remaining useful life of a battery to facilitate the replacement of the battery and determining a mitigation to extend the remaining useful life of a battery and maximize the life of the battery. The remaining useful life of a battery may correspond to a time period (e.g., a number of hours, days, weeks, months, years, etc.) until the battery is expected to reach a particular threshold at which point the battery is deemed unreliable for use.

Conventional systems for determining and extending a useful life of a battery are inefficient and unreliable because these systems do not account for impactful battery information that can provide for automatically and accurately determining a remaining useful life of a battery to facilitate the replacement of the battery. For example, these systems do not account for temperature information of a battery and state of charge information of a battery during a state of the battery (e.g., in use or not in use) over a duration of time (e.g., prior to a first use of the battery or after the first use of the battery). More specifically, conventional systems do not account for respective time periods of a battery within respective temperature ranges and respective states of charge during a first state of the battery over the duration of time, and respective time periods of the battery within respective temperature ranges and respective states of charge during a second state of the battery over the duration of time.

Additionally, conventional systems do not account for impactful environment information of a battery that can provide for automatically determining and transmitting a mitigation to a user and/or device associated with a battery to extend a remaining useful life of the battery and maximize a life of the battery. For example, operating or storing a battery (e.g., a lithium-ion battery) with a low or high state of charge at a high temperature can reduce a useful life of the battery. Yet, conventional systems do not automatically account for environment information (e.g., geography and/or weather statistics associated with a battery location, a battery storage location, a battery storage location temperature, a battery operating location, and a battery operating location temperature, etc.) of a battery to determine a mitigation (e.g., a reduced operating and/or storage temperature) to extend a remaining useful life of a battery or transmit a notification (e.g., instructions) associated with implementing the mitigation to a user and/or device associated with the battery.

As such, conventional systems suffer from a general lack of versatility and reliability because these systems do not account for impactful information, circumstances and/or conditions of a battery (e.g., temperature information, state of charge information, environmental information, etc.) that can provide for automatically and accurately determining a remaining useful life of a battery to facilitate the replacement of the battery and determining a mitigation to extend the remaining useful life of a battery and maximize the life of the battery.

Overall, this lack of versatility and reliability causes conventional systems to provide underwhelming performance and reduce the efficiency and general timeliness of performing facility tasks. Conventional systems rely on and perform periodic or ad hoc battery services (e.g., status checks, maintenance, and/or replacements) to prevent or reduce the probability of a battery and/or a device that relies on power from the battery from becoming inoperable due to an end of a useful life of the battery and/or the probability of a battery becoming ineffective and incapable of supporting the functioning of a facility but these battery services can be inefficient and/or ineffective. For example, performing battery maintenance too frequently (e.g., when a battery has sufficient remaining useful life) can result in unnecessary downtime of a device associated with a battery thereby causing inefficient use of the device and/or inefficient performance of a system utilizing the device. Alternatively, if such battery services are performed infrequently, a useful life of a battery may end between battery services, and, as such, a battery and an associated device and/or system may be rendered inoperable.

Additionally, these battery services can be manual (e.g., rely on human intervention) and, as such, can be time-consuming and cost-prohibitive (e.g., increased associate labor costs) due to the quantity (e.g., tens, hundreds, thousands, etc.) of batteries requiring services, and subject to human error (e.g., quantifying a remaining useful life of a battery). Further, the large quantity of batteries renders performing battery services for each battery impractical, if not impossible. Additionally, these battery services can generally yield binary results including, but not limited to, a “good” or “bad” status of a battery, a replacement or non-replacement of a battery, and the like. Thus, such battery services can be cost prohibitive by resulting in a large number of battery replacements because the battery services do not consider a mitigation to extend a remaining useful life of a battery or transmit a notification (e.g., instructions) associated with implementing the mitigation to a user and/or device associated with the battery.

Thus, it is an objective of the present disclosure to eliminate these and other problems with conventional systems and methods via devices and methods that can automatically and accurately determine a remaining useful life of a battery to facilitate the replacement of the battery and determine a mitigation to extend the remaining useful life of a battery and maximize a life of the battery.

In accordance with the above, and with the disclosure herein, the present disclosure includes improvements in computer functionality or in improvements to other technologies at least because the present disclosure describes that, e.g., information systems, and their related various components, may be improved or enhanced with the disclosed dynamic device features and methods that provide for the efficient utilization of batteries and improved management of batteries and associated devices for system administrators. That is, the present disclosure describes improvements in the functioning of an information system itself or “any other technology or technical field” (e.g., the field of distributed and/or commercial information systems). For example, the disclosed dynamic device features and methods improve and enhance the automatic determination of a remaining useful life of a battery to facilitate the replacement of the battery and determination of a mitigation to extend the remaining useful life of a battery and maximize a life of the battery.

This mitigates (if not eliminates) human error and eliminates inefficiencies (e.g., inoperability of batteries and devices associated therewith and batteries becoming ineffective and incapable of supporting the functioning of a facility) typically experienced over time by systems lacking such features and methods. This improves the state of the art at least because such previous systems are inefficient as they lack the ability to automatically and accurately determine a remaining useful life of a battery to facilitate the replacement of the battery and determine a mitigation to extend the remaining useful life of a battery and maximize the life of the battery. In this way, the devices and methods obviate manually monitoring and analyzing each battery associated with a device deployed within a facility and facilitate the efficiency and general timeliness of performing facility tasks.

The present disclosure also applies various features and functionality, as described herein, with, or by use of, a particular machine, e.g., a processor, a mobile device (e.g., a phone, a wearable, a mobile computer, a tablet, a barcode scanner, a QR code scanner, an RFID reader, a robot, etc.) and/or other hardware components as described herein. Moreover, the present disclosure includes specific features other than what is well-understood, routine, conventional activity in the field, or adds unconventional steps that demonstrate, in various embodiments, particular useful applications, e.g., determining a remaining useful life of a battery to facilitate the replacement of the battery and determining a mitigation to extend the remaining useful life of a battery and maximize the life of the battery.

Accordingly, it would be highly beneficial to develop a system, device and method that can automatically and accurately determine a remaining useful life of a battery to facilitate the replacement of a battery and determine a mitigation to extend the remaining useful life of a battery and maximize the life of the battery. The systems, devices and methods of the present disclosure address these and other needs.

In an embodiment, the present disclosure is directed to a method. The method comprises: receiving temperature information of a first battery and state of charge information of the first battery over a duration of time; receiving metric data of the first battery over the duration of time; training a machine learning model based on historical data associated with one or more other batteries; utilizing the trained machine learning model to determine a remaining useful life of the first battery based on the temperature information, the state of charge information, and the metric data; generating, based on the determined remaining useful life of the first battery, a notification associated with the first battery; and transmitting at least one of the remaining useful life of the first battery and the notification.

In an embodiment, the present disclosure is directed to a device comprising one or more processors and a non-transitory computer-readable memory coupled to the one or more processors. The memory stores instructions thereon that, when executed by the one or more processors, cause the one or more processors to: receive temperature information of a first battery and state of charge information of the first battery over a duration of time; receive metric data of the first battery over the duration of time; train a machine learning model based on historical data associated with one or more other batteries; utilize the trained machine learning model to determine a remaining useful life of the first battery based on the temperature information, the state of charge information, and the metric data; generate, based on the determined remaining useful life of the first battery, a notification associated with the first battery; and transmit at least one of the remaining useful life of the first battery and the notification.

In an embodiment, the present disclosure is directed to a system. The system comprises at least one device having a first battery; a server having one or more processors; and a non-transitory computer-readable memory coupled to the device, the server, and the one or more processors. The memory stores instructions thereon that, when executed by the one or more processors, cause the one or more processors to: receive temperature information of a first battery and state of charge information of the first battery over a duration of time; receive metric data of the first battery over the duration of time; train a machine learning model based on historical data associated with one or more other batteries; utilize the trained machine learning model to determine a remaining useful life of the first battery based on the temperature information, the state of charge information, and the metric data; generate, based on the determined remaining useful life of the first battery, a notification associated with the first battery; and transmit at least one of the remaining useful life of the first battery and the notification.

In an embodiment, the present disclosure is directed to a method. The method comprises: receiving temperature information of a first battery and state of charge information of the first battery over a duration of time; receiving metric data of the first battery over the duration of time; receiving environment information of the first battery; training a machine learning model based on historical data associated with one or more other batteries; utilizing the trained machine learning model to determine at least one mitigation to extend a remaining useful life of the first battery based on the temperature information, the state of charge information, the metric data, and the environment information; and transmitting, based on the determination, at least one of the at least one mitigation to extend the remaining useful life of the first battery and a notification.

In an embodiment, the present disclosure is directed to a device comprising one or more processors and a non-transitory computer-readable memory coupled to the one or more processors. The memory stores instructions thereon that, when executed by the one or more processors, cause the one or more processors to: receive temperature information of a first battery and state of charge information of the first battery over a duration of time; receive metric data of the first battery over the duration of time; receive environment information of the first battery; train a machine learning model based on historical data associated with one or more other batteries; utilize the trained machine learning model to determine at least one mitigation to extend a remaining useful life of the first battery based on the temperature information, the state of charge information, the metric data, and the environment information; and transmit, based on the determination, at least one of the at least one mitigation to extend the remaining useful life of the first battery and a notification.

In an embodiment, the present disclosure is directed to a system. The system comprises at least one device having a first battery; a server having one or more processors; and a non-transitory computer-readable memory coupled to the device, the server, and the one or more processors. The memory stores instructions thereon that, when executed by the one or more processors, cause the one or more processors to: receive temperature information of a first battery and state of charge information of the first battery over a duration of time; receive metric data of the first battery over the duration of time; receive environment information of the first battery; train a machine learning model based on historical data associated with one or more other batteries; utilize the trained machine learning model to determine at least one mitigation to extend a remaining useful life of the first battery based on the temperature information, the state of charge information, the metric data, and the environment information; and transmit, based on the determination, at least one of the at least one mitigation to extend the remaining useful life of the first battery and a notification.

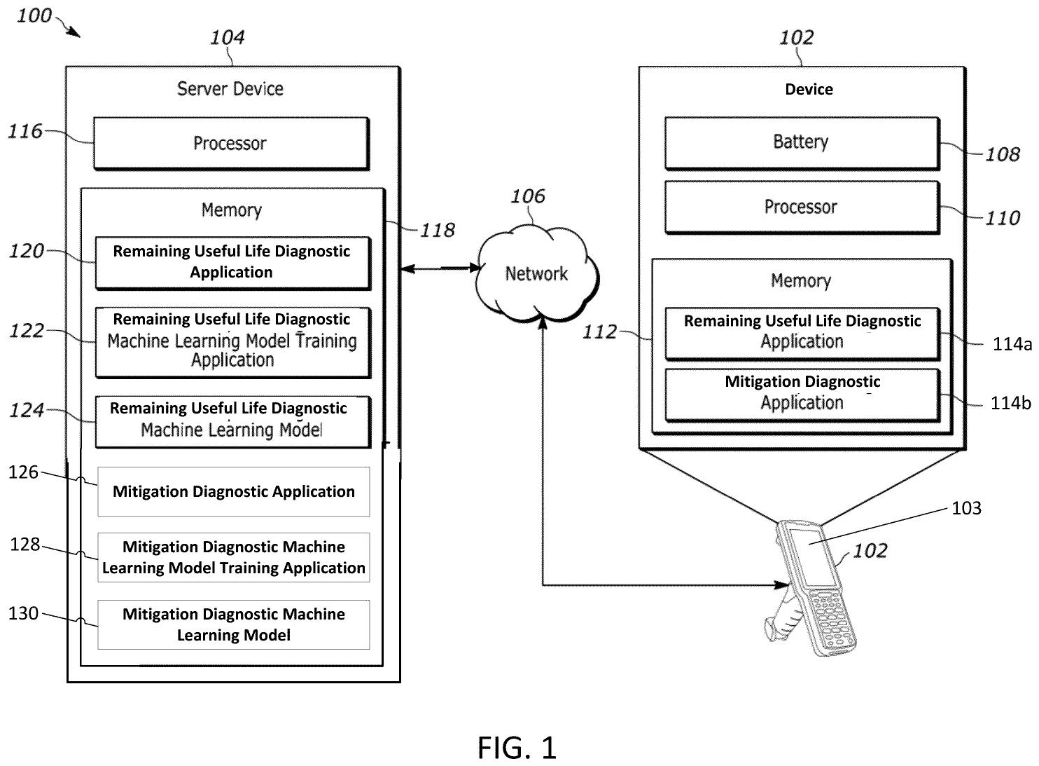

Turning to the Drawings, FIG. 1 is a diagram 100 illustrating an embodiment of a system of the present disclosure. FIG. 1 illustrates a system 100 for determining and extending a remaining useful life of a battery. The system 100 can be deployed in a facility (e.g., a hardware store, a warehouse, a fulfillment center, a grocery store, a convenience store, a retail store, a hospital, an airport, a manufacturing plant, a shipping center, etc.) and utilize a device 102 (e.g., a phone, a wearable, a mobile computer, a tablet, a barcode scanner, a QR code scanner, an RFID reader, a robot, etc.) or a fleet (e.g., tens, hundreds, thousands, etc.) of devices 102 having respective one or more batteries 108 to assist with the execution of tasks and workflows in the facility. For example, an associate of a facility can utilize a device 102 to identify each item displayed on a display module of the facility by scanning each item and/or processing an associated label thereof (e.g., a SKU or a product code). Additionally, based on the identification, an associate can perform other tasks including, but not limited to, locating, picking, and/or re-stocking each item displayed on the display module. The device 102 or fleet of devices 102 may rely on the respective one or more batteries 108 to store and supply power to the device 102 or the fleet of devices 102 and components thereof. As shown, the system 100 includes one or more devices 102, which may communicate with a server device 104 via a network 106 (and/or via a wired interface, not shown).

The device 102 can include a display 103, a battery 108, a processor 110, and a memory 112 storing one or more applications 114 (e.g., a remaining useful life diagnostic application 114a and a mitigation diagnostic application 114b). The device 102 may be at least one of a computing device (e.g., a desktop computer), a mobile computing device (e.g., a phone, a wearable, a tablet, a laptop, etc.), and a specialized mobile computing device (e.g., a barcode scanner, a QR-code scanner, an RFID reader, a robot, etc.). The display 103 can include any one of, or a suitable combination of, a touch screen, haptics, and a graphical user interface (GUI) integrated with and/or displayed the display 103. In addition to the display 103, the device 102 can also include one or more other output devices, such as a speaker, a notification light-emitting diode (LED), and the like (not shown). A device 102 may include a network interface (not shown) indicative of any suitable type of communication interface(s) (e.g., wired interfaces such as Ethernet or USB, and/or any suitable wireless interfaces) configured to operate in accordance with any suitable protocol(s) for communicating with the server 104 over the network 106. The network interface therefore includes a suitable combination of hardware elements (e.g., transceivers, antenna elements and the like) and accompanying firmware to enable such communication.

A device 102 may include a battery 108. For example, the battery 108 may be a lithium-ion battery. In another example, the battery 108 may be a smart battery including a battery memory and one or more battery processors storing computer-readable instructions that cause the one or more battery processors to store information including, but not limited to, battery temperature information, battery state of charge information, battery usage, and the like on the battery memory.

A device 102 may include a processor 110 (e.g., one or more central processing units (CPUs)), interconnected with a non-transitory computer readable storage medium, such as a memory 112 and a communications interface (not shown). For example, the processor 110 may be one or more microprocessors, controllers, and/or any suitable type of processors and may comprise one or more integrated circuits.

The memory 112 includes a combination of volatile memory (e.g., Random Access Memory or RAM) and non-volatile memory (e.g., read only memory or ROM, Electrically Erasable Programmable Read Only Memory or EEPROM, flash memory). The memory 112 stores computer readable instructions for execution by the processor 110 and may comprise one or more integrated circuits.

The memory 112 stores a remaining useful life diagnostic application 114a and a mitigation diagnostic application 114b (also referred to simply as applications 114a and 114b) which, when executed by the processor 110, configures the processor 110 to perform various functions described below in greater detail and related to automatically and accurately determining a remaining useful life of a battery to facilitate the replacement of the battery and determining a mitigation to extend the remaining useful life of a battery and maximize the life of the battery.

More specifically, the application 114a, when executed by the processor 110, configures the processor 110 to perform various functions including, but not limited to, utilizing a trained machine learning model to determine a remaining useful life of a battery 108 based on temperature information of the battery 108, state of charge information of the battery 108, and metric data of the battery 108; generating, based on the determined remaining useful life of the battery 108, a notification associated with the battery 108; and transmitting at least one of the remaining useful life of the battery and the notification. The notification can include, but is not limited to, a status, an email, an alert, and a software patch to enable a change in settings in at least one of a battery 108 and an associated device 102. The notification can be transmitted to a user and/or a device 102 associated with a battery 108 and can be displayed on the display 103 of the device 102. Additionally, the application 114b, when executed by the processor 110, configures the processor 110 to perform various functions including, but not limited to, utilizing a trained machine learning model to determine at least one mitigation to extend a remaining useful life of a battery based on temperature information of the battery, state of charge information of the battery, metric data of the battery, and environment information of the battery; and transmitting, based on the determination, at least one of the at least one mitigation to extend the remaining useful life of the battery and a notification. In this way, the processor provides for automatically and accurately determining a remaining useful life of a battery to facilitate the replacement of the battery and determining a mitigation to extend the remaining useful life of a battery and maximize the life of the battery. As described below, this functionality can also be executed by the processor 116 of the server device 104.

The applications 114a and 114b may also be implemented as a suite of distinct applications in other examples. Those skilled in the art will appreciate that the functionality implemented by the processor 110 via the execution of the applications 114a and 114b may also be implemented by one or more specially designed hardware and firmware components, such as field-programmable gate arrays (FPGAs), application-specific integrated circuits (ASICs) and the like in other embodiments.

The server device 104 can include a processor 116 and a memory 118 storing one or more applications (e.g., a remaining useful life diagnostic application 120, a remaining useful life diagnostic machine learning model training application 122, a remaining useful life diagnostic machine learning model 124, a mitigation diagnostic application 126, a mitigation diagnostic machine learning model training application 128, and a mitigation diagnostic machine learning model 130). A server device 104 may include a network interface (not shown) indicative of any suitable type of communication interface(s) (e.g., wired interfaces such as Ethernet or USB, and/or any suitable wireless interfaces) configured to operate in accordance with any suitable protocol(s) for communicating with the device 102 over the network 106. The network interface therefore includes a suitable combination of hardware elements (e.g., transceivers, antenna elements and the like) and accompanying firmware to enable such communication.

A server device 104 may include a processor 116 (e.g., one or more CPUs), interconnected with a non-transitory computer readable storage medium, such as a memory 118 and an interface (not shown). For example, the processor 116 may be one or more microprocessors, controllers, and/or any suitable type of processors and may comprise one or more integrated circuits.

The memory 118 includes a combination of volatile memory (e.g., Random Access Memory or RAM) and non-volatile memory (e.g., read only memory or ROM, Electrically Erasable Programmable Read Only Memory or EEPROM, flash memory). The memory 118 stores computer readable instructions for execution by the processor 116 and may comprise one or more integrated circuits.

The memory 118 stores a remaining useful life diagnostic application 120, a remaining useful life diagnostic machine learning model training application 122, a remaining useful life diagnostic machine learning model 124, a mitigation diagnostic application 126, a mitigation diagnostic machine learning model training application 128, and a mitigation diagnostic machine learning model 130 (also respectively referred to simply as applications 120, 122, 124, 126, 128 and 130) which, when executed by the processor 116, configures the processor 116 to perform various functions described below in greater detail and related to automatically and accurately determining a remaining useful life of a battery to facilitate the replacement of the battery and determining a mitigation to extend the remaining useful life of a battery and maximize the life of the battery.

More specifically, the application 120, when executed by the processor 116, configures the processor 116 to perform various functions including, but not limited to, receiving temperature information of a battery 108 and state of charge information of the battery 108 over a duration of time and metric data of the battery 108 over the duration of time. The temperature information of the battery 108 and the state of charge information of the battery 108 are indicative of at least one of respective time periods of the battery 108 within respective temperature ranges and respective states of charge during a first state of the battery 108 over the duration of time, and respective time periods of the battery 108 within respective temperature ranges and respective states of charge during a second state of the battery 108 over the duration of time. Additionally, the first state of the battery 108 is indicative of the battery 108 being in use, the second state of the battery 108 is indicative of the battery 108 not being in use, and the duration of time is indicative of at least one of a first time period prior to first use of the battery 108 and a second time period after the first use of the battery 108. The metric data of the battery 108 is indicative of at least one of a battery identification, a time stamp, a battery total cumulative charge, a battery present charge level, a battery present capacity, a battery rated capacity, a battery health percentage, a battery discharge rate, a battery cycle, a battery temperature, an average current, an average power, a voltage, charge on/off events, a battery charge source, and battery swap data, over the duration of time.

The battery 108 can capture and store the temperature information, state of charge information, and metric data of the battery 108 over the duration of time when the battery 108 is in use (e.g., the first state) and when the battery 108 is not in use (e.g., the second state). Additionally, the captured and stored temperature information, state of charge information, and metric data of a battery 108 associated with when the battery 108 is in use and not in use can be transmitted by a device 102 via a network 106 and received by a server device 104 when the battery 108 is coupled to (e.g., connected to and/or inserted into) the device 102. In this way, the system 100 can capture temperature information, state of charge information, and metric data of a battery 108 when the battery 108 is not in use (e.g., prior to a first use of the battery and/or not coupled to a device 102).

The remaining useful life diagnostic application 120 may analyze (e.g., using a simulation, such as a Monte-Carlo simulation, and/or using a machine learning model, such as the remaining useful life diagnostic model 124 discussed in greater detail below) the temperature information of a battery 108 and state of charge information of the battery 108 over a duration of time and metric data of the battery 108 over the duration of time to determine a remaining useful life of a battery 108 to facilitate the replacement of the battery 108.

It should be noted that the remaining useful life diagnostic application 120 may receive and analyze additional data in combination with the temperature information of a battery 108 and state of charge information of the battery 108 over a duration of time and metric data of the battery 108 over the duration of time to determine a remaining useful life of a battery 108 to facilitate the replacement of the battery 108. For example, the remaining useful life diagnostic application 120 may receive and analyze usage data of a battery 108 and data of an associated device 102. The usage data of the battery 108 can be indicative of a usage of the battery 108 with an associated device 102 over a duration of time and/or charge cycles of the battery 108 over the duration of time. For example, the usage data of the battery 108 may identify usage rates and/or usage patterns (e.g., usage rates over a duration of time) of the battery 108. Additionally, or alternatively, the usage data of the battery 108 may identify charge cycles and/or characteristics of the battery 108 relative to the charge cycles. For example, such characteristics may include a maximum charge capacity associated with a charge cycle (e.g., a maximum amount of charge, in milliampere hours (mAh), received or counted during the charge cycle). Correspondingly, the usage data of the battery 108 may indicate degradation rates (e.g., historical degradation rates) of the battery 108 over the duration of time.

In an embodiment, the trained remaining useful life diagnostic machine learning model 124 may be executed on the server device 104, while in other embodiments, the remaining useful life diagnostic machine learning model 124 may be executed on another computing system (not shown), separate from the server device 104. For example, the server device 104 may transmit the temperature information of a battery 108 and state of charge information of the battery 108 over a duration of time, metric data of the battery 108 over the duration of time, and, optionally, additional data (e.g., usage data of a battery 108 and data of an associated device 102) to another computing system, where the trained remaining useful life diagnostic machine learning model 124 is applied to data corresponding to the temperature information of the battery 108 and state of charge information of the battery 108 over the duration of time, the metric data of the battery 108 over the duration of time, and the additional data. The other computing system may determine and transmit to the server device 104 a remaining useful life of a battery 108 based upon applying the remaining useful life diagnostic machine learning model 124 to one or more of the temperature information of the battery 108 and state of charge information of the battery 108 over the duration of time, the metric data of the battery 108 over the duration of time, and the additional data.

In an embodiment, the remaining useful life diagnostic machine learning model 124 may be trained by the remaining useful life diagnostic machine learning model training application 122 executing on the server device 104, while in other embodiments, the remaining useful life diagnostic machine learning model 124 may be trained by a machine learning model training application executing on another computing system, separate from the server device 104.

Whether the remaining useful life diagnostic machine learning model 124 is trained on the server device 104 or elsewhere, the remaining useful life diagnostic machine learning model 124 may be trained (e.g., by the remaining useful life diagnostic machine learning model training application 122) using training data from a server device 104, a device 102, a battery 108, and/or historical data including historical data of one or more other batteries associated with a battery 108, historical data of a device 102 associated with a battery 108, and historical additional data associated with a battery 108. The training data may be received periodically, according to a schedule, and/or based on an event (e.g., an end of a charge cycle of a battery 108).

The historical data of the one or more other batteries can be associated with a battery 108 based on at least one of: a temperature information of a battery 108 and a state of charge information of a battery 108 being having a threshold degree of correspondence to historical patterns of temperature information of the one or more other batteries and state of charge information of the one or more other batteries over a duration of time; metric data of the battery 108 having a threshold degree of correspondence to historical metric data of the one or more other batteries over the duration of time; usage data of the battery 108 having a threshold degree of correspondence to historical usage data of the one or more other batteries; and a type of the battery 108 having a threshold degree of correspondence to the one or more other batteries. The system 100 can dynamically set each threshold degree of correspondence based on weights, factors, and/or margins associated with each of the temperature information, the state of charge information, the metric data, the environment information, the usage data, and the battery type or a user can set the threshold degree of correspondence.

As mentioned above, the system 100 can be deployed in a facility and utilize a device 102 or a fleet (e.g., tens, hundreds, thousands, etc.) of devices 102 having respective one or more batteries 108 to assist with the execution of tasks and workflows. As such, the historical data of the one or more other batteries may correspond to tens, hundreds, and thousands of batteries. The historical data may include any suitable data structure, such as a database, an index, a graph, and/or the like. The training data may correspond to historical data that is captured and/or received from a server device 104, a device 102, and a battery 108 during a training period involved in developing and/or generating the remaining useful life diagnostic machine learning model training application 122.

The trained machine learning model 124 may then be applied to new temperature information of a battery 108 and state of charge information of the battery 108 over a duration of time and metric data of the battery 108 over the duration of time to determine a remaining useful life of a battery 108 to facilitate the replacement of the battery 108. For example, the trained machine learning model 124 can determine that a time period associated with a remaining useful life of a battery 108 is below a threshold, schedule a replacement of the battery 108 based on the time period, and transmit a notification associated with the replacement of the battery 108 to at least one of a user and a device 102 associated with the battery 108. The notification can be displayed on the display 103 of the device 102. Additionally, the trained machine learning model 124 may also be applied to new additional data (e.g., usage data of a battery 108 and data of an associated device 102) in combination with new temperature information of a battery 108 and state of charge information of the battery 108 over a duration of time and metric data of the battery 108 over the duration of time to determine a remaining useful life of a battery 108 to facilitate the replacement of the battery 108.

In various aspects, the remaining useful life diagnostic machine learning model 124 may comprise a machine learning program or algorithm that may be trained by and/or employ a neural network, which may be a deep learning neural network, or a combined learning module or program that learns in one or more features or feature datasets in particular area(s) of interest. The machine learning programs or algorithms may also include natural language processing, semantic analysis, automatic reasoning, regression analysis, support vector machine (SVM) analysis, decision tree analysis, random forest analysis, K-Nearest neighbor analysis, naïve Bayes analysis, clustering, reinforcement learning, and/or other machine learning algorithms and/or techniques.

In some embodiments, the artificial intelligence and/or machine learning based algorithms used to train the remaining useful life diagnostic machine learning model 124 may comprise a library or package executed on the server device 104 (or other computing devices not shown in FIG. 1). For example, such libraries may include, but are not limited to, the TENSORFLOW based library, the PYTORCH library, and/or the SCIKIT-LEARN Python library.

Machine learning, as referenced herein, may involve identifying and recognizing patterns in existing data (such as training a model 124 based upon historical data including historical data of one or more batteries associated with a battery 108, historical data of a device 102 associated with a battery 108, and historical additional data associated with a battery 108) to facilitate a determination or identification for subsequent data (such as utilizing the machine learning model 124 on new temperature information of a battery 108 and state of charge information of the battery 108 over a duration of time, metric data of the battery 108, and, optionally, additional data (e.g., usage data of a battery 108 and data of an associated device 102)) to determine a remaining useful life of a battery 108 to facilitate the replacement of the battery 108.

The application 126, when executed by the processor 116, configures the processor 116 to perform various functions including, but not limited to, receiving temperature information of a battery 108 and state of charge information of the battery 108 over a duration of time, metric data of the battery 108 over the duration of time, and environment information of the battery 108. As mentioned above, the temperature information of the battery 108 and the state of charge information of the battery 108 are indicative of at least one of respective time periods of the battery 108 within respective temperature ranges and respective states of charge during a first state of the battery 108 over the duration of time, and respective time periods of the battery 108 within respective temperature ranges and respective states of charge during a second state of the battery 108 over the duration of time. Additionally, the first state of the battery 108 is indicative of the battery 108 being in use, the second state of the battery 108 is indicative of the battery 108 not being in use, and the duration of time is indicative of at least one of a first time period prior to first use of the battery 108 and a second time period after the first use of the battery 108. The metric data of the battery 108 is indicative of at least one of a battery identification, a time stamp, a battery total cumulative charge, a battery present charge level, a battery present capacity, a battery rated capacity, a battery health percentage, a battery discharge rate, a battery cycle, a battery temperature, an average current, an average power, a voltage, charge on/off events, a battery charge source, and battery swap data, over the duration of time.

The environment information of a battery 108 is indicative of one or more present and/or historical conditions (e.g., operating, storage, location, geography, weather, climate, etc.) associated with the battery 108 and/or an associated device 102. The environment information of a battery 108 is indicative of at least one of a shipping destination of a battery 108, a shipping method of a battery 108, geography associated with a battery 108 location, historical weather statistics associated with a battery 108 location, present weather associated with a battery 108 location, a battery 108 storage location, a battery 108 storage location temperature, a battery 108 operating location, and a battery 108 operating location temperature.

As mentioned above, conventional systems do not account for impactful environment information of a battery 108 that can provide for automatically determining and transmitting a mitigation to a user and/or device associated with a battery to extend a remaining useful life of the battery and maximize a life of the battery. For example, operating or storing a battery (e.g., a lithium-ion battery) with a low or high state of charge at a high temperature can reduce a useful life of the battery. Yet, conventional systems do not automatically account for environment information of a battery 108 to determine a mitigation (e.g., a reduced operating and/or storage temperature) to extend a remaining useful life of a battery or transmit a notification (e.g., instructions) associated with implementing the mitigation to a user and/or device associated with the battery 108.

The battery 108 can capture and store the temperature information, state of charge information, and metric data of the battery 108 over the duration of time when the battery 108 is in use (e.g., the first state) and when the battery 108 is not in use (e.g., the second state). Additionally, the captured and stored temperature information, state of charge information, and metric data of a battery 108 associated with when the battery 108 is in use and not in use can be transmitted by a device 102 via a network 106 and received by a server device 104 when the battery 108 is coupled to (e.g., connected to and/or inserted into) the device 102. In this way, the system 100 can capture temperature information, state of charge information, and metric data of a battery 108 when the battery 108 is not in use (e.g., prior to a first use of the battery and/or not coupled to a device 102).

The mitigation diagnostic application 126 may analyze (e.g., using a simulation, such as a Monte-Carlo simulation, and/or using a machine learning model, such as the mitigation diagnostic machine learning model 130 discussed in greater detail below) the temperature information of a battery 108 and state of charge information of the battery 108 over a duration of time, the metric data of the battery 108 over the duration of time, and the environment information to determine a mitigation to extend a remaining useful life of a battery 108 to maximize the life of the battery 108.

It should be noted that the mitigation diagnostic application 126 may receive and analyze additional data in combination with the temperature information of a battery 108 and state of charge information of the battery 108 over a duration of time, the metric data of the battery 108 over the duration of time, and the environment information to a mitigation to extend a remaining useful life of a battery 108 to maximize the life of the battery 108. For example, the mitigation diagnostic application 126 may receive and analyze usage data of a battery 108 and data of an associated device 102. The usage data of the battery 108 can be indicative of a usage of the battery 108 with an associated device 102 over a duration of time and/or charge cycles of the battery 108 over the duration of time. For example, the usage data of the battery 108 may identify usage rates and/or usage patterns (e.g., usage rates over a duration of time) of the battery 108. Additionally, or alternatively, the usage data of the battery 108 may identify charge cycles and/or characteristics of the battery 108 relative to the charge cycles. For example, such characteristics may include a maximum charge capacity associated with a charge cycle (e.g., a maximum amount of charge, in milliampere hours (mAh), received or counted during the charge cycle). Correspondingly, the usage data of the battery 108 may indicate degradation rates (e.g., historical degradation rates) of the battery 108 over the duration of time.

In an embodiment, the trained mitigation diagnostic machine learning model 128 may be executed on the server device 104, while in other embodiments, the mitigation diagnostic machine learning model 128 may be executed on another computing system (not shown), separate from the server device 104. For example, the server device 104 may transmit the temperature information of a battery 108 and state of charge information of the battery 108 over a duration of time, metric data of the battery 108 over the duration of time, environment information, and, optionally, additional data (e.g., usage data of a battery 108 and data of an associated device 102) to another computing system, where the trained mitigation diagnostic machine learning model 128 is applied to data corresponding to the temperature information of the battery 108 and state of charge information of the battery 108 over the duration of time, the metric data of the battery 108 over the duration of time, the environment information, and, optionally, the additional data. The other computing system may determine and transmit to the server device 104 a mitigation to extend a remaining useful life of a battery 108 to maximize the life of the battery 108 based upon applying the mitigation diagnostic machine learning model 130 to one or more of the temperature information of the battery 108 and state of charge information of the battery 108 over the duration of time, the metric data of the battery 108 over the duration of time, the environment information, and, optionally, the additional data.

In an embodiment, the mitigation diagnostic machine learning model 130 may be trained by the mitigation diagnostic machine learning model training application 128 executing on the server device 104, while in other embodiments, the mitigation diagnostic machine learning model 130 may be trained by a machine learning model training application executing on another computing system, separate from the server device 104.

Whether the mitigation diagnostic machine learning model 130 is trained on the server device 104 or elsewhere, the mitigation diagnostic machine learning model 130 may be trained (e.g., by the mitigation diagnostic machine learning model training application 128) using training data from a server device 104, a device 102, a battery 108, and/or historical data including historical data of one or more other batteries associated with a battery 108, historical data of a device 102 associated with a battery 108, historical environment information, and, optionally, historical additional data associated with a battery 108. The training data may be received periodically, according to a schedule, and/or based on an event (e.g., an end of a charge cycle of a battery 108).

The historical data of the one or more other batteries can be associated with a battery 108 based on at least one of: a temperature information of a battery 108 and a state of charge information of a battery 108 being having a threshold degree of correspondence to historical patterns of temperature information of the one or more other batteries and state of charge information of the one or more other batteries over a duration of time; metric data of the battery 108 having a threshold degree of correspondence to historical metric data of the one or more other batteries over the duration of time; environment information of the battery 108 having a threshold degree of correspondence to historical environment information of the one or more other batteries; usage data of the battery 108 having a threshold degree of correspondence to historical usage data of the one or more other batteries; and a type of the battery 108 having a threshold degree of correspondence to the one or more other batteries.

The system 100 can dynamically set each threshold degree of correspondence based on weights, factors, and/or margins associated with each of the temperature information, the state of charge information, the metric data, the environment information, the usage data, and the battery type or a user can set the threshold degree of correspondence.

As mentioned above, the system 100 can be deployed in a facility and utilize a device 102 or a fleet (e.g., tens, hundreds, thousands, etc.) of devices 102 having respective one or more batteries 108 to assist with the execution of tasks and workflows. As such, the historical data of the one or more other batteries may correspond to tens, hundreds, and thousands of batteries. The historical data may include any suitable data structure, such as a database, an index, a graph, and/or the like. The training data may correspond to historical data that is captured and/or received from a server device 104, a device 102, and a battery 108 during a training period involved in developing and/or generating the mitigation diagnostic machine learning model training application 128.

The trained machine learning model 130 may then be applied to new temperature information of a battery 108 and state of charge information of the battery 108 over a duration of time and metric data of the battery 108 over the duration of time to determine a mitigation to extend a remaining useful life of a battery 108 to maximize the life of the battery 108. For example, the trained mitigation machine learning model 130 can determine at least one mitigation and transmit instructions associated with implementing the at least one mitigation to extend the remaining useful life of the battery 108 to at least one of a user and a device 102 associated with the battery 108. The notification can include, but is not limited to, instructions for implementing a mitigation, an alert, a software patch to enable a change in settings in at least one of a battery 108 and an associated device 102. The notification can be displayed on the display 103 of the device 102. Additionally, the trained mitigation machine learning model 130 may also be applied to new additional data (e.g., usage data of a battery 108 and data of an associated device 102) in combination with new temperature information of a battery 108 and state of charge information of the battery 108 over a duration of time, metric data of the battery 108 over the duration of time, and environment information to determine a mitigation to extend a remaining useful life of a battery 108 to maximize the life of the battery 108.

In various aspects, the mitigation diagnostic machine learning model 130 may comprise a machine learning program or algorithm that may be trained by and/or employ a neural network, which may be a deep learning neural network, or a combined learning module or program that learns in one or more features or feature datasets in particular area(s) of interest. The machine learning programs or algorithms may also include natural language processing, semantic analysis, automatic reasoning, regression analysis, support vector machine (SVM) analysis, decision tree analysis, random forest analysis, K-Nearest neighbor analysis, naïve Bayes analysis, clustering, reinforcement learning, and/or other machine learning algorithms and/or techniques.

In some embodiments, the artificial intelligence and/or machine learning based algorithms used to train the remaining useful life diagnostic machine learning model 124 may comprise a library or package executed on the server device 104 (or other computing devices not shown in FIG. 1). For example, such libraries may include, but are not limited to, the TENSORFLOW based library, the PYTORCH library, and/or the SCIKIT-LEARN Python library.

Machine learning, as referenced herein, may involve identifying and recognizing patterns in existing data (such as training a model 130 based on historical data including historical data of one or more batteries associated with a battery 108, historical data of a device 102 associated with a battery 108, historical environment information, and, optionally, historical additional data associated with a battery 108) to facilitate a determination or identification for subsequent data (such as utilizing the machine learning model 130 on new temperature information of a battery 108 and state of charge information of the battery 108 over a duration of time, metric data of the battery 108, environment information, and, optionally, additional data (e.g., usage data of a battery 108 and data of an associated device 102)) to determine a mitigation to extend a remaining useful life of a battery 108 to maximize the life of the battery 108.

Machine learning model(s) may be created and trained based upon example data (e.g., “training data”) inputs or data (which may be termed “features” and “labels”) to make valid and reliable predictions for new inputs, such as testing level or production level data or inputs. In supervised machine learning, a machine learning program operating on a server, computing device, or otherwise processor(s), may be provided with example inputs (e.g., “features”) and their associated, or observed, outputs (e.g., “labels”) for the machine learning program or algorithm to determine or discover rules, relationships, patterns, or otherwise machine learning “models” that map such inputs (e.g., “features”) to the outputs (e.g., labels), for example, by determining and/or assigning weights or other metrics to the model across its various feature categories. Such rules, relationships, or otherwise models may then be provided to subsequent inputs for the model, executing on the server, computing device, or otherwise processor(s), to predict, based upon the discovered rules, relationships, or model, an expected output.

In unsupervised machine learning, the server, computing device, or otherwise processor(s), may be required to find its own structure in unlabeled example inputs, where, for example multiple training iterations are executed by the server, computing device, or otherwise processor(s) to train multiple generations of models until a satisfactory model, e.g., a model that provides sufficient prediction accuracy when given test level or production level data or inputs, is generated. The disclosures herein may use one or both of such supervised or unsupervised machine learning techniques.

In addition, the memory 118 may also store additional machine readable instructions, including any of one or more application(s), one or more software component(s), and/or one or more application programming interfaces (APIs), which may be implemented to facilitate or perform the features, functions, or other disclosure described herein, such as any methods, processes, elements or limitations, as illustrated, depicted, or described for the various flowcharts, illustrations, diagrams, figures, and/or other disclosure herein. It should be appreciated that one or more other applications may be envisioned and that are executed by the processor(s) 116. It should be appreciated that given the state of advancements of computing devices, the processes, functions, and steps described herein as being performed by the server device 104 may be performed by a computing device, such as the device 102, or a smart battery, such as the battery 108.

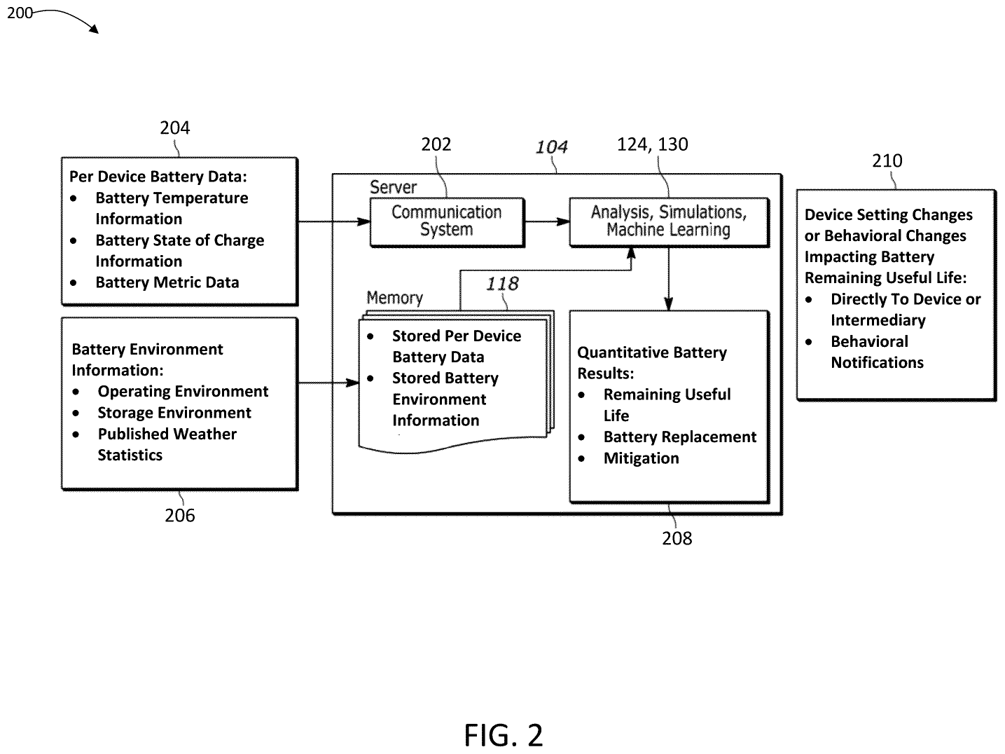

FIG. 2 is a diagram 200 illustrating a server device 104 of FIG. 1 in accordance with an embodiment of the present disclosure. As shown in FIG. 2, the server device 104 may include a communication system 202, which may facilitate a wired or wireless connection between the server 104 and the device 102, and may receive the data associated with the battery 108 and/or the device 102 from the battery 108 and/or the device 102. For instance, as shown at block 204, the data associated with the battery 108 and/or the device 102 may include, but is not limited to, battery temperature information, battery state of charge information, and battery metric data. As shown at block 206, the server device 104 may further receive battery environment information including, but not limited to, an operating environment, a storage environment, and published weather statistics.

The server device 104 may store the data from blocks 204 and 206 on the memory 118. The server device 104 may analyze the data stored on the memory 118 using one or more simulations (e.g., Monte Carlo simulations) or machine learning models (e.g., machine learning models 124 and 130 discussed in greater detail above). As shown at block 208, the server 104 may determine quantitative battery results including, but not limited to, a remaining useful life of a battery, a battery replacement, and a mitigation. Furthermore, the server device 104 may generate recommended device 102 setting changes or behavioral changes impacting a battery remaining useful life, and may transmit these recommended device setting changes or behavioral changes directly to a device 102 or to an intermediary associated with the device 102. For instance, these recommended device setting changes or behavioral changes may be provided to a user of a device 102 as a notification, or may be provided to the device 102 directly as a configuration file or update to the device 102.

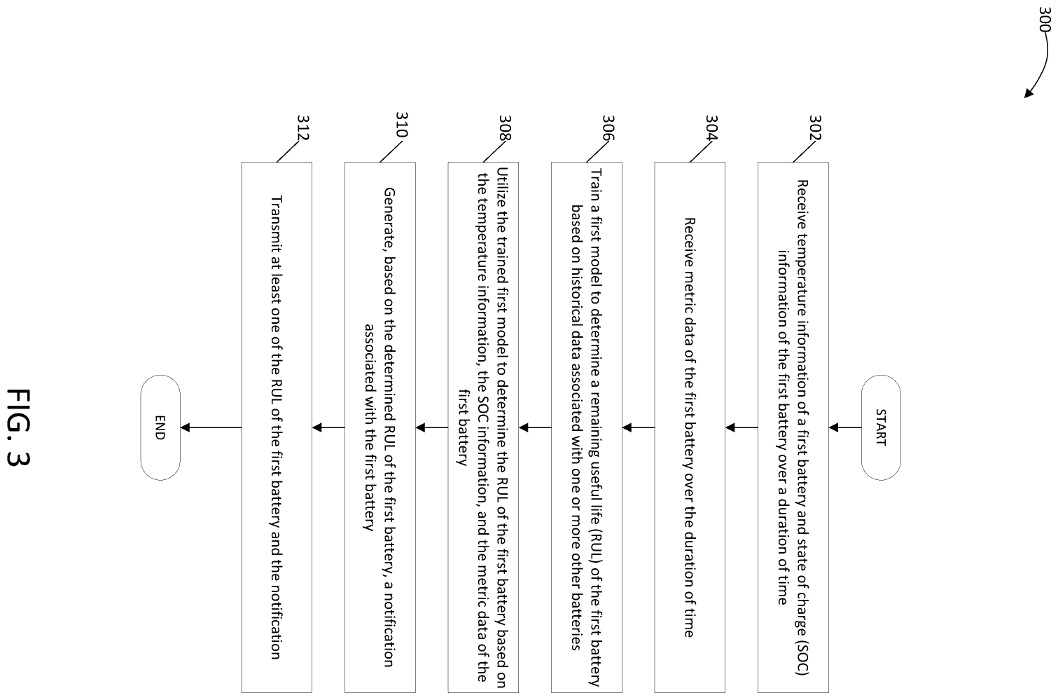

FIG. 3 is a flowchart illustrating processing steps 300 carried out by an embodiment of the present disclosure. The processing steps will be described in conjunction with their performance in the system (e.g., by the server 104 or the server 104 in conjunction with the device 102). In general, via performance of the processing steps, the system can automatically and accurately determine a remaining useful life of a battery to facilitate the replacement of the battery. Beginning in step 302, the system receives temperature information of a first battery and state of charge information of the first battery over a duration of time. In step 304, the system receives metric data of the first battery over the duration of time. Then, in step 306, the system trains a first model to determine a remaining useful life of the first battery based on historical data associated with one or more other batteries. In step 308, the system utilizes the trained first model to determine a remaining useful life of the first battery based on the temperature information, the state of charge information, and the metric data of the first battery. Then, in step 310, the system generates, based on the determined remaining useful life of the first battery, a notification associated with the first battery. In step 312, the system transmits at least one of the remaining useful life of the first battery and the notification.

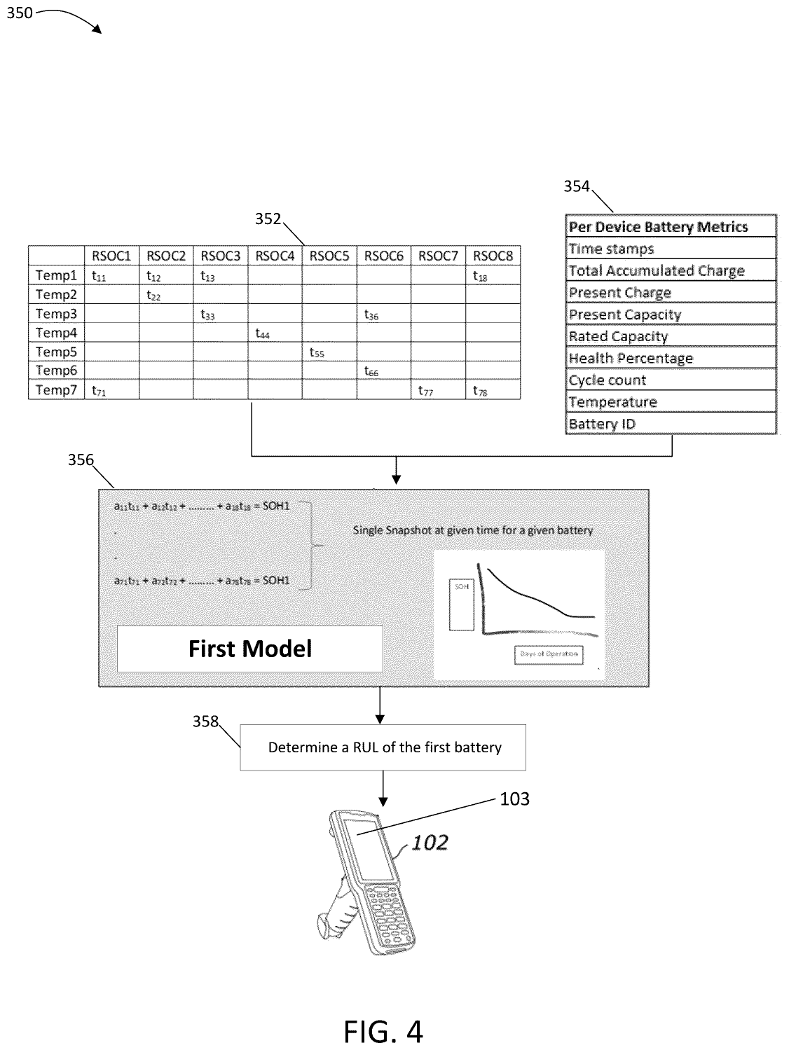

FIG. 4 is a diagram 350 illustrating one or more processing steps carried out by the embodiment of FIG. 3. As shown in FIG. 4, a first model 356 can receive a matrix 352 indicative of temperature information (e.g., temperature values Temp1, Temp2, Temp3, Temp4, Temp5, Temp6, and Temp7) of a battery 108 and state of charge information (e.g., RSOC8) of a battery 108 over a duration of time and metric data 354 of a battery 108 over the duration of time.

Developments in battery gauge technology provide for capturing a period of time by a battery 108 in a given temperature range within a given state of charge range. Referring to the matrix 352, each cell of the matrix 352 is indicative of a cumulative period of time by a battery 108 in a combined range of temperature and state of charge values. For example, t11 is indicative of a cumulative period of time (from a first use of a battery 108) by a battery 108 in a range combination (Temp1, RSOC1) where Temp1 can be indicative of a temperature below 0° C. and RSOC1 can be indicative of a state of charge>95%. Temperature values and state of charge values can be different across a variety of distinct batteries based on one or more of a battery type, a battery chemistry, a battery part number, a battery size, and the like. Additionally, the temperature and state of charge ranges can be non-linear. For example, temperature ranges can be indicative of 0° C. to 10° C.; 10° C. to 20° C.; 20° C. to 45° C.; 45° C. to 50° C.; and 50° C. to 60° C. and state of charge ranges can be indicative of 0 to 5%; 5 to 10%; 10 to 20%; 20 to 50%; 50 to 80%; 80 to 90%; 90 to 95%; and 95 to 100%. Temperature and state of charge ranges can be dynamically adjusted by the system or a user based a cell type and battery usage data.

The metric data 354 of the battery 108 is indicative of at least one of a battery identification, a time stamp, a battery total cumulative charge, a battery present charge level, a battery present capacity, a battery rated capacity, a battery health percentage, a battery discharge rate, a battery cycle, a battery temperature, an average current, an average power, a voltage, charge on/off events, a battery charge source, and battery swap data, over the duration of time.

A battery 108 can capture and store temperature information, state of charge information, and metric data of a battery 108 over a duration of time when a battery 108 is in use and when a battery 108 is not in use. Additionally, the captured and stored temperature information, state of charge information, and metric data of a battery 108 associated with when the battery 108 is in use and not in use can be transmitted by a device 102 via a network 106 and received by a server device 104 when the battery 108 is coupled to (e.g., connected to and/or inserted into) the device 102. In this way, the system 100 can capture temperature information, state of charge information, and metric data of a battery 108 when the battery 108 is not in use (e.g., prior to a first use of the battery and/or not coupled to a device 102).

The first model 356 can correlate a state of health of a battery 108 to each period of time of a battery 108 in a cell of combined range of temperature and state of charge values. A machine learning problem can include a state of health of a battery 108 as a target variable (e.g., SOH1). For example, as shown in FIG. 4, a single snapshot for a given time for a battery 108 can be given by Equation 1 below:

$$\begin{matrix}{a}_{11} {t}_{11} + {a}_{12} {t}_{12} + … + {a}_{18} {t}_{18} = SOH 1 \\ . \\ . \\ {a}_{71} {t}_{71} + {a}_{72} {t}_{72} + … + {a}_{78} {t}_{78} = SOH 1\end{matrix} \} \qquad Equation 1$$

where the coefficient tᵢⱼ is indicative of a period of time of a battery 108 in a cell of the matrix 352 of combined range of temperature and state of charge values (e.g., i refers to an ith column and j refers to a jth row of the matrix 352) and the coefficient aᵢⱼ is determined during training of the first model 356 and is indicative of a forecasted state of health of a battery 108 at a future time based on different combinations of tᵢⱼ.

The system can utilize similar equations for snapshots of respective batteries across the life of the respective batteries where the coefficient aᵢⱼ can be determined by utilizing a machine learning model and/or technique (e.g., a regression technique). These sets of equations can be solved to determine the coefficient aᵢⱼ where the coefficient aᵢⱼ can be specific to a part number of a battery and a rated capacity of a battery.

As shown in FIG. 4, the system can graph a state of health of a battery 108 against days of operation (e.g., time) of a battery 108 where the days of operation can be given by ΣΣtᵢⱼ. A graph of a state of health of a battery 108 against days of operation (e.g., time) of a battery 108 can provide for determining when a respective battery 108 may reach a specified threshold (e.g., a remaining useful life of a battery 108 given by a number of days). Utilizing a plurality of such graphs, the system can generate a machine learning model regarding a population of batteries for a given part number and/or rated capacity. For example, the system can determine a state of health derivative for each battery among a population of batteries and combine the determined state of health derivatives across different time periods of operation to generate a model that can account for the non-linear behavior of a state of health of a battery 108 against days of operation (e.g., time) of a battery 108.

In step 358, the system utilizes the first model 356 to determine a remaining useful life of a battery 108 based on the matrix 352 indicative of the temperature information and the state of charge information of a battery 108 and the metric data 354 of a battery 108. Then, the system generates, based on the determined remaining useful life of the battery 108, a notification associated with the battery 108 and transmits at least one of the remaining useful life of the battery 108 and the notification. The notification can include, but is not limited to, a status, an email, an alert, and a software patch to enable a change in settings in at least one of a battery 108 and an associated device 102. The notification can be transmitted to a user and/or a device 102 associated with a battery 108 and can be displayed on the display 103 of the device 102.

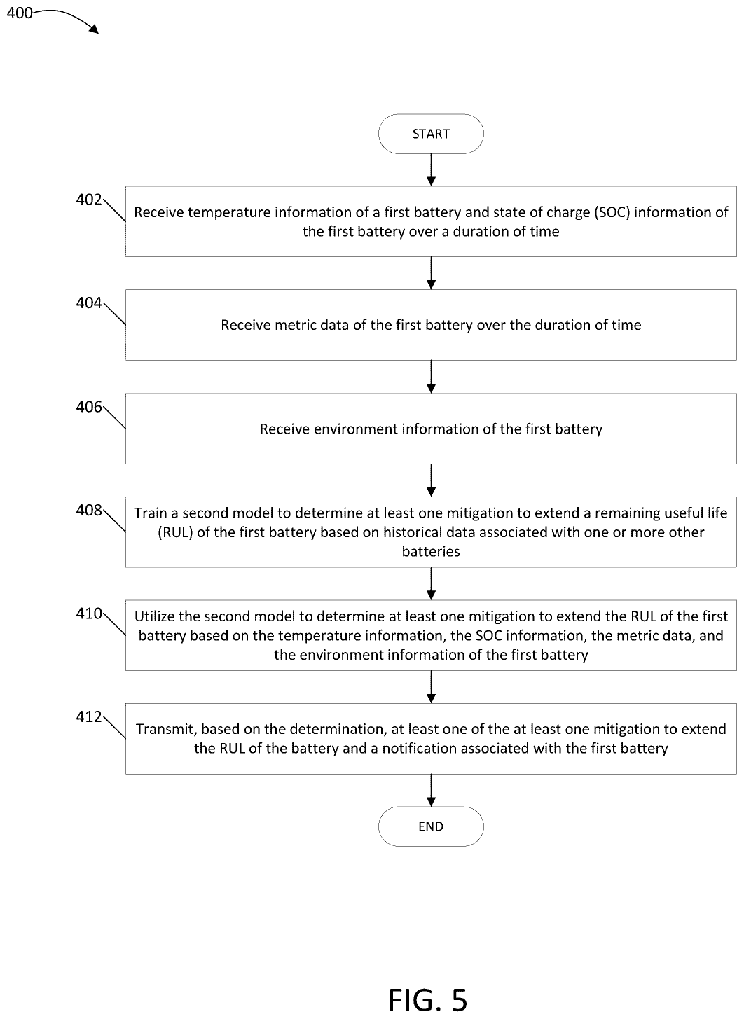

FIG. 5 is a flowchart illustrating processing steps 400 carried out by an embodiment of the present disclosure. The processing steps will be described in conjunction with their performance in the system (e.g., by the server 104 or the server 104 in conjunction with the device 102). In general, via performance of the processing steps, the system can automatically determine a mitigation to extend the useful life of a battery and maximize the life of the battery. Beginning in step 402, the system receives temperature information of a first battery and state of charge information of the first battery over a duration of time. In step 404, the system receives metric data of the first battery over the duration of time. Then, in step 406, the system receives environment information of the first battery. In step 408, the system trains a second model to determine at least one mitigation to extend a remaining useful life of the first battery based on historical data associated with one or more other batteries. In step 410, the system utilizes the trained first model to determine at least one mitigation to extend the remaining useful life of the first battery based on the temperature information, the state of charge information, the metric data, and the environment information of the first battery. Then, in step 412, the system transmits, based on the determination, at least one of the at least one mitigation to extend the remaining useful life of the first battery and a notification associated with the first battery.

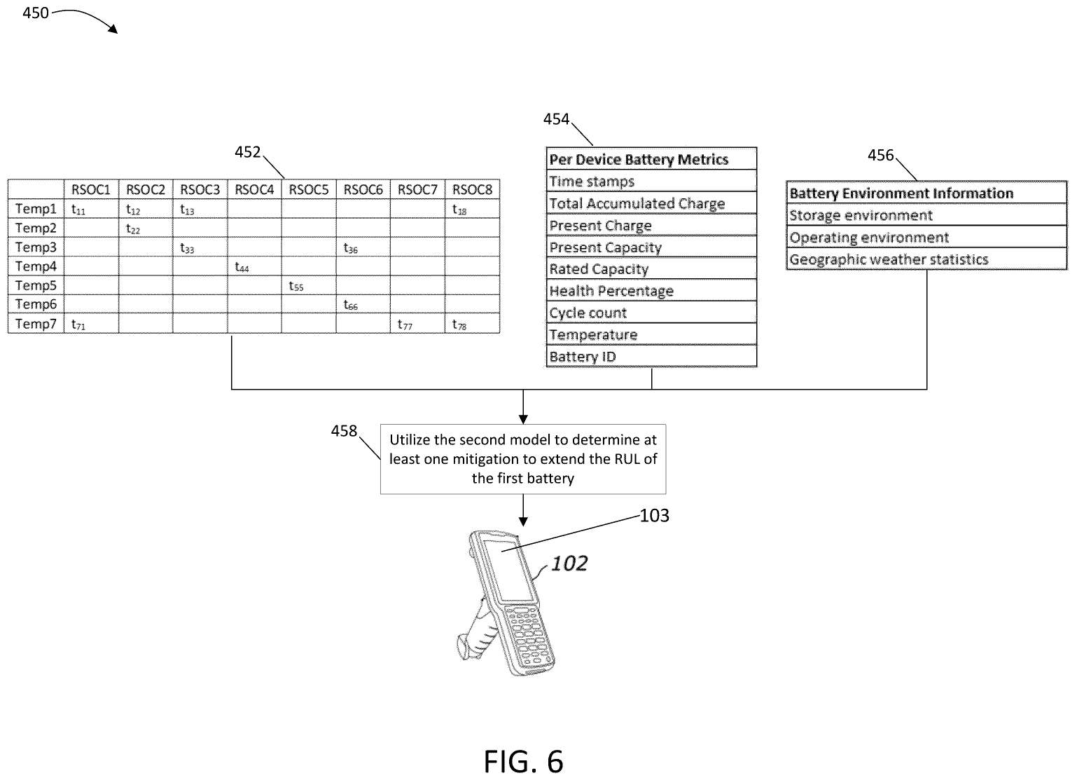

FIG. 6 is a diagram 450 illustrating one or more processing steps carried out by the embodiment of FIG. 5. As shown in FIG. 6, a second model 458 can receive a matrix 452 indicative of temperature information (e.g., temperature values Temp1, Temp2, Temp3, Temp4, Temp5, Temp6, and Temp7) of a battery 108 and state of charge information (e.g., RSOC8) of a battery 108 over a duration of time, metric data 454 of a battery 108 over the duration of time and environment information 456 of a battery 108.

Developments in battery gauge technology provide for capturing a period of time by a battery 108 in a given temperature range within a given state of charge range. Referring to the matrix 452, each cell of the matrix 352 is indicative of a cumulative period of time by a battery 108 in a combined range of temperature and state of charge values. For example, t11 is indicative of a cumulative period of time (from a first use of a battery 108) by a battery 108 in a range combination (Temp1, RSOC1) where Temp1 can be indicative of a temperature below 0° C. and RSOC1 can be indicative of a state of charge>95%. Temperature values and state of charge values can be different across a variety of distinct batteries based on one or more of a battery type, a battery chemistry, a battery part number, a battery size, and the like. Additionally, the temperature and state of charge ranges can be non-linear. For example, temperature ranges can be indicative of 0° C. to 10° C.; 10° C. to 20° C.; 20° C. to 45° C.; 45° C. to 50° C.; and 50° C. to 60° C. and state of charge ranges can be indicative of 0 to 5%; 5 to 10%; 10 to 20%; 20 to 50%; 50 to 80%; 80 to 90%; 90 to 95%; and 95 to 100%. Temperature and state of charge ranges can be dynamically adjusted by the system or a user based a cell type and battery usage data.

The metric data 454 of the battery 108 is indicative of at least one of a battery identification, a time stamp, a battery total cumulative charge, a battery present charge level, a battery present capacity, a battery rated capacity, a battery health percentage, a battery discharge rate, a battery cycle, a battery temperature, an average current, an average power, a voltage, charge on/off events, a battery charge source, and battery swap data, over the duration of time.

The environment information 456 of a battery 108 is indicative of one or more present and/or historical conditions (e.g., operating, storage, location, geography, weather, climate, etc.) associated with the battery 108 and/or an associated device 102. For example, the environment information of a battery 108 is indicative of at least one of a shipping destination of a battery 108, a shipping method of a battery 108, geography associated with a battery 108 location, historical weather statistics associated with a battery 108 location, present weather associated with a battery 108 location, a battery 108 storage location, a battery 108 storage location temperature, a battery 108 operating location, and a battery 108 operating location temperature.

The system utilizes the second model 458 to determine at least one mitigation to extend a remaining useful life of a battery 108 based on the matrix 452 indicative of the temperature information and the state of charge information of a battery 108, the metric data 454 of a battery 108, and the environment information 456.

The system can train a machine learning model to yield coefficients aᵢⱼ and can solve for potential values of tᵢⱼ to determine a state of health of a battery 108 under at least one operating condition and/or constraint. For example, a device 102 could be required to operate at 45° C. for two hours a day which limits a useful life of an associated battery 108 and impacts a remaining useful life of the associated battery 108. Additionally, operating the device 102 at 45° C. beyond the required daily two hours further limits the useful life of the associated battery 108 and impacts the remaining useful life of the associated battery 108. The system can quantify an impact on a useful life of the associated battery 108 from operating the device 102 at 45° C. beyond the required daily two hours and, in response to quantifying the impact, determine at least one optimal value of tᵢⱼ to extend the remaining useful life of the associated battery 108 while accounting for the temperature information and the state of charge information of the battery 108, the metric data 454 of the battery 108, and the environment information 456.

For example, the second model 458 can determine at least one mitigation and transmit instructions associated with implementing the at least one mitigation to extend the remaining useful life of the battery 108 to at least one of a user and a device 102 associated with the battery 108. The notification can include, but is not limited to, instructions for implementing a mitigation, an alert, a software patch to enable a change in settings in at least one of a battery 108 and an associated device 102. The notification can be displayed on the display 103 of the device 102.

As mentioned above, conventional systems do not account for impactful environment information of a battery 108 that can provide for automatically determining and transmitting a mitigation to a user and/or device associated with a battery to extend a remaining useful life of the battery and maximize a life of the battery. For example, operating or storing a battery (e.g., a lithium-ion battery) with a low or high state of charge at a high temperature can reduce a useful life of the battery. Yet, conventional systems do not automatically account for environment information of a battery 108 to determine a mitigation (e.g., a reduced operating and/or storage temperature) to extend a remaining useful life of a battery or transmit a notification (e.g., instructions) associated with implementing the mitigation to a user and/or device associated with the battery 108.

A battery 108 can capture and store temperature information, state of charge information, and metric data of a battery 108 over a duration of time when a battery 108 is in use and when a battery 108 is not in use. Additionally, the captured and stored temperature information, state of charge information, and metric data of a battery 108 associated with when the battery 108 is in use and not in use can be transmitted by a device 102 via a network 106 and received by a server device 104 when the battery 108 is coupled to (e.g., connected to and/or inserted into) the device 102. In this way, the system 100 can capture temperature information, state of charge information, and metric data of a battery 108 when the battery 108 is not in use (e.g., prior to a first use of the battery and/or not coupled to a device 102).

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

Certain expressions may be employed herein to list combinations of elements. Examples of such expressions include: “at least one of A, B, and C”; “one or more of A, B, and C”; “at least one of A, B, or C”; “one or more of A, B, or C”. Unless expressly indicated otherwise, the above expressions encompass any combination of A and/or B and/or C.

It will be appreciated that some embodiments may be comprised of one or more specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed:

1. A method comprising:
receiving temperature information of a first battery and state of charge information of the first battery over a duration of time;
receiving metric data of the first battery over the duration of time;
training a machine learning model based on historical data associated with one or more other batteries;
utilizing the trained machine learning model to determine a remaining useful life of the first battery based on the temperature information, the state of charge information, and the metric data;
generating, based on the determined remaining useful life of the first battery, a notification associated with the first battery; and
transmitting at least one of the remaining useful life of the first battery and the notification.

2. The method of claim 1, wherein the temperature information of the first battery and the state of charge information of the first battery are indicative of at least one of respective time periods of the first battery within respective temperature ranges and respective states of charge during a first state of the first battery over the duration of time, and respective time periods of the first battery within respective temperature ranges and respective states of charge during a second state of the first battery over the duration of time.

3. The method of claim 2, wherein
the first state of the first battery is indicative of the first battery being in use,
the second state of the first battery is indicative of the first battery not being in use, and
the duration of time is indicative of at least one of a first time period prior to a first use of the first battery and a second time period after the first use of the first battery.

4. The method of claim 1, wherein the metric data of the first battery is indicative of at least one of a battery identification, a time stamp, a battery total cumulative charge, a battery present charge level, a battery present capacity, a battery rated capacity, a battery health percentage, a battery discharge rate, a battery cycle, a battery temperature, an average current, an average power, a voltage, charge on/off events, a battery charge source, and battery swap data, over the duration of time.

5. The method of claim 1, wherein the one or more other batteries are associated with the first battery based on at least one of:
the temperature information of the first battery and the state of charge information of the first battery having a threshold degree of correspondence to historical patterns of temperature information of the one or more other batteries and state of charge information of the one or more other batteries over the duration of time;
the metric data of the first battery having a threshold degree of correspondence to historical metric data of the one or more other batteries over the duration of time;
usage data of the first battery having a threshold degree of correspondence to historical usage data of the one or more other batteries; and
a type of the first battery having a threshold degree of correspondence to the one or more other batteries.

6. The method of claim 1, further comprising:
determining that a time period associated with the remaining useful life of the first battery is below a threshold;
scheduling a replacement of the first battery based on the time period; and
transmitting a notification associated with the replacement of the first battery to at least one of a user and a device associated with the first battery.

7. A device, comprising:
one or more processors; and
a non-transitory computer-readable memory coupled to the one or more processors, the memory storing instructions thereon that, when executed by the one or more processors, cause the one or more processors to:
receive temperature information of a first battery and state of charge information of the first battery over a duration of time,
receive metric data of the first battery over the duration of time,
train a machine learning model based on historical data associated with one or more other batteries,
utilize the trained machine learning model to determine a remaining useful life of the first battery based on the temperature information, the state of charge information, and the metric data,
generate, based on the determined remaining useful life of the first battery, a notification associated with the first battery, and
transmit at least one of the remaining useful life of the first battery and the notification.

8. The device of claim 7, wherein the temperature information of the first battery and the state of charge information of the first battery are indicative of at least one of respective time periods of the first battery within respective temperature ranges and respective states of charge during a first state of the first battery over the duration of time, and respective time periods of the first battery within respective temperature ranges and respective states of charge during a second state of the first battery over the duration of time.

9. The device of claim 8, wherein
the first state of the first battery is indicative of the first battery being in use,
the second state of the first battery is indicative of the first battery not being in use, and
the duration of time is indicative of at least one of a first time period prior to a first use of the first battery and a second time period after the first use of the first battery.

10. The device of claim 7, wherein the metric data of the first battery is indicative of at least one of a battery identification, a time stamp, a battery total cumulative charge, a battery present charge level, a battery present capacity, a battery rated capacity, a battery health percentage, a battery discharge rate, a battery cycle, a battery temperature, an average current, an average power, a voltage, charge on/off events, a battery charge source, and battery swap data, over the duration of time.

11. The device of claim 7, wherein the one or more other batteries are associated with the first battery based on at least one of:
the temperature information of the first battery and the state of charge information of the first battery having a threshold degree of correspondence to historical patterns of temperature information of the one or more other batteries and state of charge information of the one or more other batteries over the duration of time,
the metric data of the first battery having a threshold degree of correspondence to historical metric data of the one or more other batteries over the duration of time,
usage data of the first battery having a threshold degree of correspondence to historical usage data of the one or more other batteries, and
a type of the first battery having a threshold degree of correspondence to the one or more other batteries.

12. The device of claim 7, wherein the instructions, when executed, further cause the one or more processors to:
determine that a time period associated with the remaining useful life of the first battery is below a threshold,
schedule a replacement of the first battery based on the time period, and
transmit a notification associated with the replacement of the first battery to at least one of a user and a device associated with the first battery.

13. A method comprising:
receiving temperature information of a first battery and state of charge information of the first battery over a duration of time;
receiving metric data of the first battery over the duration of time;
receiving environment information of the first battery;
training a machine learning model based on historical data associated with one or more other batteries;
utilizing the trained machine learning model to determine at least one mitigation to extend a remaining useful life of the first battery based on the temperature information, the state of charge information, the metric data, and the environment information; and
transmitting, based on the determination, at least one of the at least one mitigation to extend the remaining useful life of the first battery and a notification associated with the first battery.

14. The method of claim 13, wherein the temperature information of the first battery and the state of charge information of the first battery are indicative of at least one of respective time periods of the first battery within respective temperature ranges and respective states of charge during a first state of the first battery over the duration of time, and respective time periods of the first battery within respective temperature ranges and respective states of charge during a second state of the first battery over the duration of time.

15. The method of claim 14, wherein
the first state of the first battery is indicative of the first battery being in use,
the second state of the first battery is indicative of the first battery not being in use, and
the duration of time is indicative of at least one of a first time period prior to a first use of the first battery and a second time period after the first use of the first battery.

16. The method of claim 13, wherein the metric data of the first battery is indicative of at least one of a battery identification, a time stamp, a battery total cumulative charge, a battery present charge level, a battery present capacity, a battery rated capacity, a battery health percentage, a battery discharge rate, a battery cycle, a battery temperature, an average current, an average power, a voltage, charge on/off events, a battery charge source, and battery swap data, over the duration of time.

17. The method of claim 13, wherein the environment information of the first battery is indicative of at least one of a shipping destination of a battery, a shipping method of a battery, geography associated with a battery location, historical weather statistics associated with a battery location, present weather associated with a battery location, a battery storage location, a battery storage location temperature, a battery operating location, and a battery operating location temperature.

18. The method of claim 13, wherein the one or more other batteries are associated with the first battery based on at least one of:
the temperature information of the first battery and the state of charge information of the first battery having a threshold degree of correspondence to historical patterns of temperature information of the one or more other batteries and state of charge information of the one or more other batteries over the duration of time,
the metric data of the first battery having a threshold degree of correspondence to historical metric data of the one or more other batteries over the duration of time,
the environment information of the first battery having a threshold degree of correspondence to historical environment information of the one or more other batteries,
usage data of the first battery having a threshold degree of correspondence to historical usage data of the one or more other batteries, and
a type of the first battery having a threshold degree of correspondence to the one or more other batteries.

19. The method of claim 13, wherein the determined at least one mitigation to extend the remaining useful life of the first battery is a change in at least one of a shipping method of a battery, a battery storage location, a battery storage location temperature, a battery operating location, a battery operating location temperature, a battery utilization duration, a battery operating method, and a battery charging method.

20. The method of claim 13, wherein transmitting, based on the determination, the at least one of the at least one mitigation to extend the remaining useful life of the first battery and the notification comprises transmitting instructions associated with implementing the at least one mitigation to extend the remaining useful life of the first battery to at least one of a user and a device associated with the first battery.

21. A device, comprising:
one or more processors; and
a non-transitory computer-readable memory coupled to the one or more processors, the memory storing instructions thereon that, when executed by the one or more processors, cause the one or more processors to:
receive temperature information of a first battery and state of charge information of the first battery over a duration of time,
receive metric data of the first battery over the duration of time,
receive environment information of the first battery,
train a machine learning model based on historical data associated with one or more other batteries,
utilize the trained machine learning model to determine at least one mitigation to extend a remaining useful life of the first battery based on the temperature information, the state of charge information, the metric data, and the environment information, and
transmit, based on the determination, at least one of the at least one mitigation to extend the remaining useful life of the first battery and a notification associated with the first battery.

22. The device of claim 21, wherein the temperature information of the first battery and the state of charge information of the first battery are indicative of at least one of respective time periods of the first battery within respective temperature ranges and respective states of charge during a first state of the first battery over the duration of time, and respective time periods of the first battery within respective temperature ranges and respective states of charge during a second state of the first battery over the duration of time.

23. The device of claim 22, wherein
the first state of the first battery is indicative of the first battery being in use,
the second state of the first battery is indicative of the first battery not being in use, and
the duration of time is indicative of at least one of a first time period prior to a first use of the first battery and a second time period after the first use of the first battery.

24. The device of claim 21, wherein the metric data of the first battery is indicative of at least one of a battery identification, a time stamp, a battery total cumulative charge, a battery present charge level, a battery present capacity, a battery rated capacity, a battery health percentage, a battery discharge rate, a battery cycle, a battery temperature, an average current, an average power, a voltage, charge on/off events, a battery charge source, and battery swap data, over the duration of time.

25. The device of claim 21, wherein the environment information of the first battery is indicative of at least one of a shipping destination of a battery, a shipping method of a battery, geography associated with a battery location, historical weather statistics associated with a battery location, present weather associated with a battery location, a battery storage location, a battery storage location temperature, a battery operating location, and a battery operating location temperature.

26. The device of claim 21, wherein the one or more other batteries are associated with the first battery based on at least one of:
the temperature information of the first battery and the state of charge information of the first battery having a threshold degree of correspondence to historical patterns of temperature information of the one or more other batteries and state of charge information of the one or more other batteries over the duration of time;
the metric data of the first battery having a threshold degree of correspondence to historical metric data of the one or more other batteries over the duration of time;
the environment information of the first battery having a threshold degree of correspondence to historical environment information of the one or more other batteries;
usage data of the first battery having a threshold degree of correspondence to historical usage data of the one or more other batteries; and
a type of the first battery having a threshold degree of correspondence to the one or more other batteries.

27. The device of claim 21, wherein the determined at least one mitigation to extend the remaining useful life of the first battery is a change in at least one of a shipping method of a battery, a battery storage location, a battery storage location temperature, a battery operating location, a battery operating location temperature, a battery utilization duration, a battery operating method, and a battery charging method.

28. The device of claim 21, wherein transmitting, based on the determination, the at least one of the at least one mitigation to extend the remaining useful life of the first battery and the notification comprises transmitting instructions associated with implementing the at least one mitigation to extend the remaining useful life of the first battery to at least one of a user and a device associated with the first battery.
